(19) United States
(12) Patent Application Publication
(10) Pub. No.: US 2016/0359467 A1
(43) Pub. Date: Dec. 8, 2016

(54) DYNAMIC ADJUSTMENT OF POWER FOR WIRELESS POWER TRANSFER

(71) Applicant: QUALCOMM Incorporated, San Diego, CA (US)

(72) Inventors: Arvind Govindaraj, San Diego, CA (US); William Henry Von Novak, III, San Diego, CA (US)

(21) Appl. No.: 14/730,066

(22) Filed: Jun. 3, 2015

(51) Int. Cl. H03H 7/38; H01F 38/14; H02J 5/00

(52) U.S. Cl. CPC H03H 7/38; H02J 5/005; H01F 38/14

(57) ABSTRACT

An apparatus for wireless power transfer may include a resonator circuit configured to couple to an externally generated magnetic field to produce an AC current. A rectifier circuit may be configured to produce a DC signal from the AC current. A variable impedance circuit may be electrically connected as an electrical load to an output of the rectifier circuit. A control circuit may be configured to produce a control signal based on an electrical characteristic of the DC signal produced at the output of the rectifier circuit. The variable impedance circuit may be configured to change its impedance in response to the control signal of the control circuit.

### TECHNICAL FIELD

The present disclosure relates to wireless power transfer, and in particular to dynamic control in the power transfer system to manage over voltage conditions.

### BACKGROUND

Wireless power transfer is becoming increasingly popular in portable electronic devices, such as mobile phones, computer tablets, etc., which typically require long battery life and low battery weight. The ability to power an electronic device without the use of wires provides a convenient solution for users of portable electronic devices. Wireless power transfer gives manufacturers a tool for developing creative solutions to problems due to having limited power sources in consumer electronic devices.

Wireless power transfer capability can improve the user's charging experience. In a multiple device charging situation, for example, wireless power transfer may reduce overall cost (for both the user and the manufacturer) because conventional charging hardware such as power adapters and charging chords can be eliminated. There is flexibility in having different coil sizes and shapes on the transmitter and/or the receiver in terms of industrial design and support for a wide range of devices from mobile handheld devices to computer laptops.

### SUMMARY

An apparatus for wireless power transfer in accordance with the present disclosure may include a resonator circuit for coupling with an externally generated magnetic field to produce a time varying signal. The apparatus may include a rectifier for converting the time varying signal into a DC signal. A variable impedance circuit may be electrically connected to an output of the rectifier to limit the voltage level at the output of the rectifier. The variable impedance circuit may vary its impedance dependent on the DC signal at the output of the rectifier.

In some embodiments, the variable impedance circuit may present a resistive load to the output of the rectifier. In some embodiments, the variable impedance circuit may modulate its impedance in a predetermine manner.

In some embodiments, the variable impedance circuit may be controller based on one or more electrical characteristics of the DC signal. In some embodiments, the electrical characteristic of the DC signal may be its voltage level. In some embodiments, the electrical characteristic of the DC signal may be its current flow.

A method for wireless power transfer in accordance with the present disclosure may include coupling to an externally generated magnetic field to produce a time varying signal. A DC signal may be produced from the time varying signal; the DC signal being presented at an output of a circuit. One or more characteristics of the DC signal may be used to vary an impedance electrically connected to the output of the circuit.

In some embodiments, the method may include rectifying the time varying signal to produce the DC signal.

In some embodiments, the impedance may be modulated in a predetermined manner. In some embodiments, the modulation may depend on the DC signal.

An apparatus for wireless power transfer in accordance with the present disclosure may include a resonator circuit configured to generate a magnetic field that can couple to an external circuit. A power circuit may provide power to the resonator. A sense circuit may be configured to sense a parameter such as a voltage and/or current provided to the resonator coil or current drawn by the power circuit. A controller may be configured to control the power circuit in accordance with an indication that a predetermined voltage condition exists at an output of the external circuit, based on one or more of the sensed parameters.

In some embodiments, the indication may be based on one or more of the sensed voltage level in the resonator circuit, the sensed current flow in the resonator circuit, and the sensed current flow in the power circuit being modulated in a predetermined manner.

In some embodiments, the controller may gradually decrease the power provided to the resonator. In some embodiments, the controller may reduce the power provided to the resonator circuit by an amount proportional to a strength of the sensed parameter.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. In the accompanying drawings:

FIG. 1 is a functional block diagram of a wireless power transfer system in accordance with an illustrative embodiment.

FIG. 2 is a functional block diagram of a wireless power transfer system in accordance with an illustrative embodiment.

FIG. 3 is a schematic diagram of a portion of transmit circuitry or receive circuitry of FIG. 2 including a power transmitting or receiving element in accordance with an illustrative embodiment.

FIG. 4 shows receive circuitry in accordance with some embodiments of the present disclosure.

FIG. 5 illustrates operation of receive circuitry in accordance with some embodiments of the present disclosure.

FIGS. 6A, 6B, 6C, 6D show illustrative embodiments of load circuits in accordance with the present disclosure.

FIGS. 7 and 7A show embodiments of transmit circuitry in accordance with the present disclosure.

FIG. 8 illustrates operation of transmit circuitry in accordance with some embodiments of the present disclosure.

FIG. 9 demonstrates an example of load modulation in accordance with the present disclosure.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

Wireless power transfer may refer to transferring any form of energy associated with electric fields, magnetic fields, electromagnetic fields, or otherwise from a transmitter to a receiver without the use of physical electrical conductors (e.g., power may be transferred through free space). The power output into a wireless field (e.g., a magnetic field or an electromagnetic field) may be received, captured by, or coupled by a “power receiving element” to achieve power transfer.

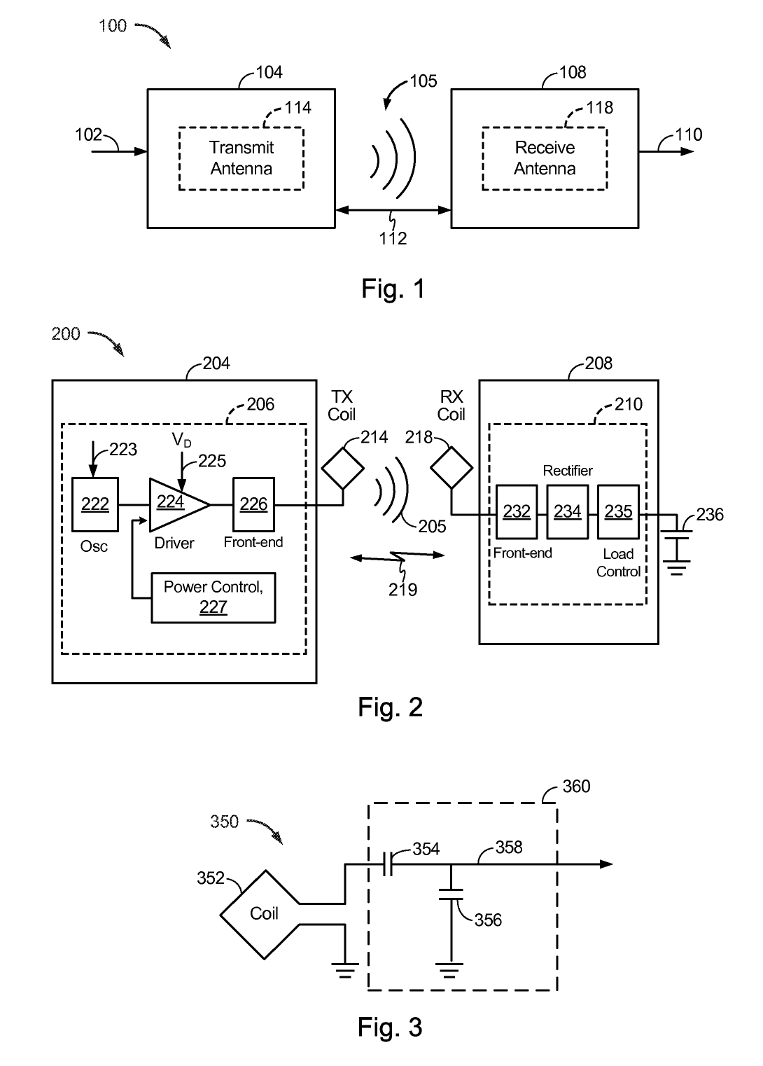

FIG. 1 is a functional block diagram of a wireless power transfer system 100, in accordance with an illustrative embodiment. Input power 102 may be provided to a transmitter 104 from a power source (not shown in this figure) to generate a wireless (e.g., magnetic or electromagnetic) field 105 for performing energy transfer. A receiver 108 may couple to the wireless field 105 and generate output power 110 for storing or consumption by a device (not shown in this figure) coupled to the output power 110. The transmitter 104 and the receiver 108 may be separated by a distance 112. The transmitter 104 may include a power transmitting element 114 for transmitting/coupling energy to the receiver 108. The receiver 108 may include a power receiving element 118 for receiving or capturing/coupling energy transmitted from the transmitter 104.

In one illustrative embodiment, the transmitter 104 and the receiver 108 may be configured according to a mutual resonant relationship. When the resonant frequency of the receiver 108 and the resonant frequency of the transmitter 104 are substantially the same or very close, transmission losses between the transmitter 104 and the receiver 108 are reduced. As such, wireless power transfer may be provided over larger distances. Resonant inductive coupling techniques may thus allow for improved efficiency and power transfer over various distances and with a variety of inductive power transmitting and receiving element configurations.

In certain embodiments, the wireless field 105 may correspond to the “near field” of the transmitter 104. The near-field may correspond to a region in which there are strong reactive fields resulting from the currents and charges in the power transmitting element 114 that minimally radiate power away from the power transmitting element 114. The near-field may correspond to a region that is within about one wavelength (or a fraction thereof) of the power transmitting element 114.

In certain embodiments, efficient energy transfer may occur by coupling a large portion of the energy in the wireless field 105 to the power receiving element 118 rather than propagating most of the energy in an electromagnetic wave to the far field.

In certain implementations, the transmitter 104 may output a time varying magnetic (or electromagnetic) field with a frequency corresponding to the resonant frequency of the power transmitting element 114. When the receiver 108 is within the wireless field 105, the time varying magnetic (or electromagnetic) field may induce a current in the power receiving element 118. As described above, if the power receiving element 118 is configured as a resonant circuit to resonate at the frequency of the power transmitting element 114, energy may be more efficiently transferred. An alternating current (AC) signal induced in the power receiving element 118 may be rectified to produce a direct current (DC) signal that may be provided to charge or to power a load.

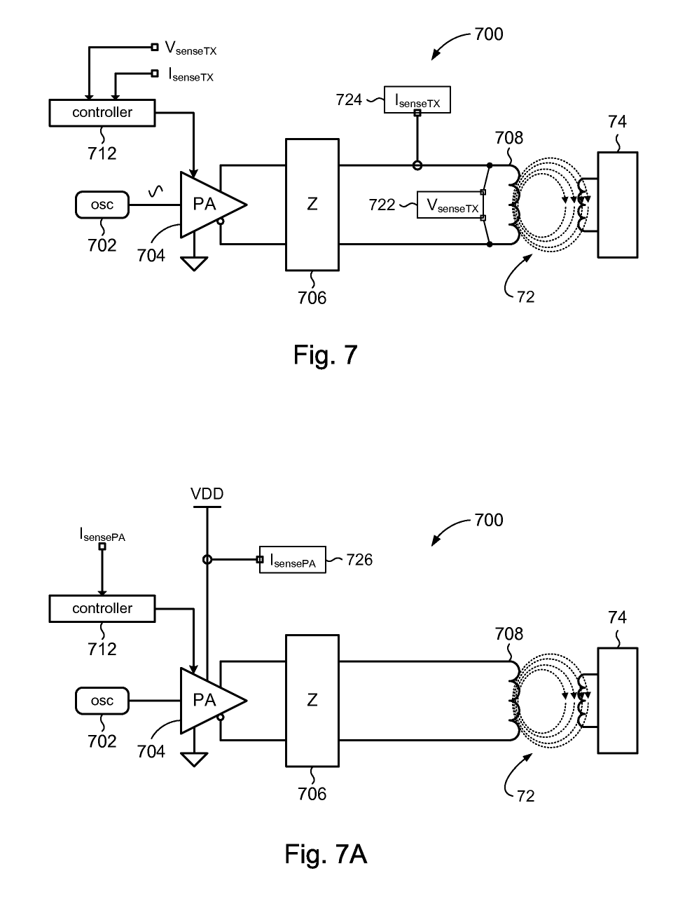

FIG. 2 is a functional block diagram of a wireless power transfer system 200, in accordance with another illustrative embodiment. The system 200 may include a transmitter 204 and a receiver 208. The transmitter 204 (also referred to herein as power transmitting unit, PTU) may include transmit circuitry 206 that may include an oscillator 222, a driver circuit 224, a front-end circuit 226, and a power control module 227. The oscillator 222 may be configured to generate a signal at a desired frequency that may adjust in response to a frequency control signal 223. The oscillator 222 may provide the oscillator signal to the driver circuit 224. The driver circuit 224 may be configured to drive the power transmitting element 214 at, for example, a resonant frequency of the power transmitting element 214 based on an input voltage signal (VD) 225. The driver circuit 224 may be a switching amplifier configured to receive a square wave from the oscillator 222 and output a sine wave. The power control module 227 may control the driver circuit 224 in accordance with the present disclosure. An example of power control module 227 will be described in more detail below in connection with controller 712 shown in FIG. 7.

The front-end circuit 226 may include a filter circuit to filter out harmonics or other unwanted frequencies. The front-end circuit 226 may include a matching circuit to match the impedance of the transmitter 204 to the power transmitting element 214. As will be explained in more detail below, the front-end circuit 226 may include a tuning circuit to create a resonant circuit with the power transmitting element 214. As a result of driving the power transmitting element 214, the power transmitting element 214 may generate a wireless field 205 to wirelessly output power at a level sufficient for charging a battery 236, or otherwise powering a load.

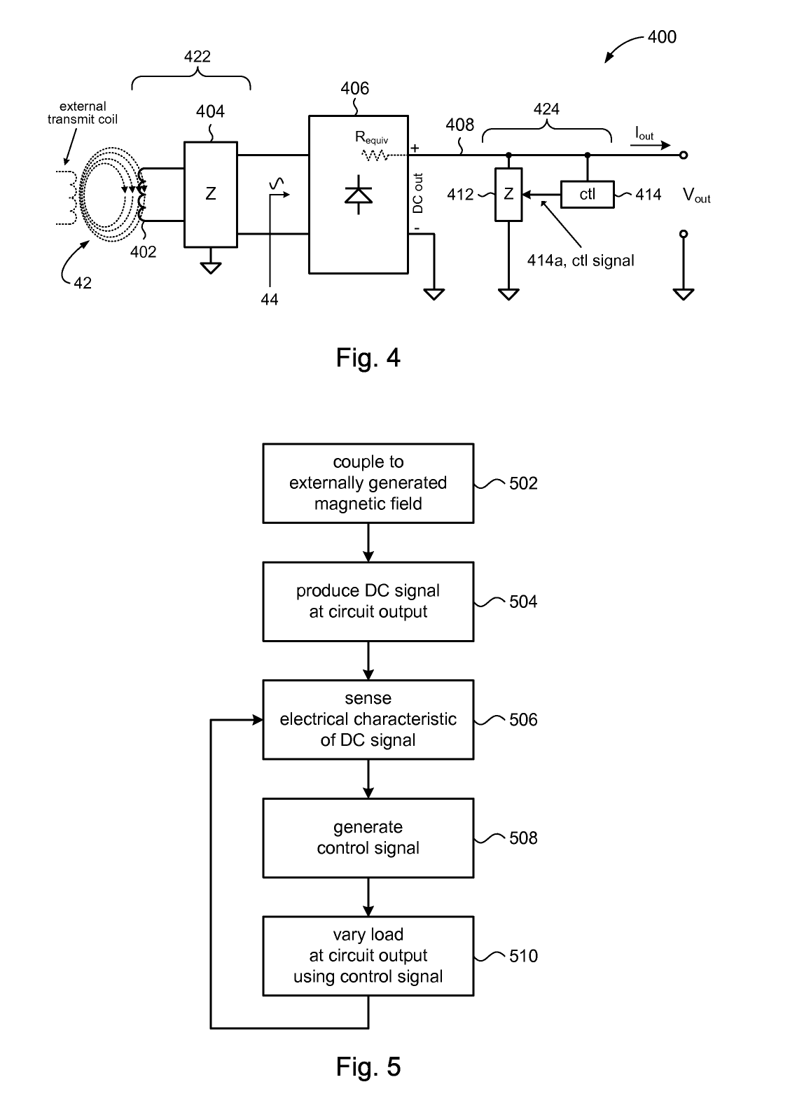

The receiver 208 (also referred to herein as power receiving unit, PRU) may include receive circuitry 210 that may include a front-end circuit 232 and a rectifier circuit 234, and a load control module 235. The front-end circuit 232 may include matching circuitry to match the impedance of the receive circuitry 210 to the power receiving element 218. As will be explained below, the front-end circuit 232 may further include a tuning circuit to create a resonant circuit with the power receiving element 218. The rectifier circuit 234 may generate a DC power output from an AC power input to charge the battery 236, as shown in FIG. 2. An example of the load control module 235 will be described in more detail below in connection with controller 414 shown in FIG. 4. The receiver 208 and the transmitter 204 may additionally communicate on a separate communication channel 219 (e.g., Bluetooth, Zigbee, cellular, etc.). The receiver 208 and the transmitter 204 may alternatively communicate via in-band signaling using characteristics of the wireless field 205.

The receiver 208 may be configured to determine whether an amount of power transmitted by the transmitter 204 and received by the receiver 208 is appropriate for charging the battery 236. Transmitter 204 may be configured to generate a predominantly non-radiative field with a direct field coupling coefficient (k) for providing energy transfer. Receiver 208 may directly couple to the wireless field 205 and may generate an output power for storing or consumption by a battery (or load) 236 coupled to the output or receive circuitry 210.

As discussed above, transmitter 204 and receiver 208 may be separated by a distance and may be configured according to a mutual resonant relationship to minimize transmission losses between the transmitter and the receiver.

FIG. 3 is a schematic diagram showing additional details of the transmit circuitry 206 or the receive circuitry 210 of FIG. 2, in accordance with illustrative embodiments. As illustrated in FIG. 3, transmit or receive circuitry 350 may include a power transmitting or receiving element 352 and a tuning circuit 360. The power transmitting or receiving element 352 may also be referred to or be configured as an antenna or a “loop” antenna. The term “antenna” generally refers to a component that may wirelessly output or receive energy for coupling to another “antenna.” The power transmitting or receiving element 352 may also be referred to herein or be configured as a “magnetic” antenna, or an induction coil, a resonator, or a portion of a resonator. The power transmitting or receiving element 352 may also be referred to as a coil or resonator of a type that is configured to wirelessly output or receive power. As used herein, the power transmitting or receiving element 352 is an example of a “power transfer component” of a type that is configured to wirelessly output and/or receive power. The power transmitting or receiving element 352 may include an air core or a physical core such as a ferrite core (not shown in this figure).

When the power transmitting or receiving element 352 is configured as a resonant circuit or resonator with tuning circuit 360, the resonant frequency of the power transmitting or receiving element 352 may be based on inductance and capacitance. Inductance may be simply the inductance created by a coil or other inductor forming the power transmitting or receiving element 352, and the capacitance (e.g., a capacitor) may be provided by the tuning circuit 360 to create a resonant structure at a desired resonant frequency. As a non limiting example, the tuning circuit 360 may comprise a capacitor 354 and a capacitor 356 may be added to the transmit and/or receive circuitry 350 to create a resonant circuit.

The tuning circuit 360 may include other components to form a resonant circuit with the power transmitting or receiving element 352. As another non limiting example, the tuning circuit 360 may include a capacitor (not shown) placed in parallel between the two terminals of the circuitry 350. Still other designs are possible. In some embodiments, the tuning circuit in the front-end circuit 226 may have the same design (e.g., 360) as the tuning circuit in front-end circuit 232. In other embodiments, the front-end circuit 226 may use a tuning circuit design different than in the front-end circuit 232.

For power transmitting elements, the signal 358, with a frequency that substantially corresponds to the resonant frequency of the power transmitting or receiving element 352, may be an input to the power transmitting or receiving element 352. For power receiving elements, the signal 358, with a frequency that substantially corresponds to the resonant frequency of the power transmitting or receiving element 352, may be an output from the power transmitting or receiving element 352.

As explained above, in accordance with aspects of certain embodiments, a wireless power system 200 (FIG. 2) may operate by sending a specific current through a power transmitting element 214 in a wireless power transmitter 204, which in turn can induce a voltage in the power receiving element 218 of a receiver 208. High voltages induced in the receiver 208 can potentially damage the electronics in the receiver 208, and thus should be avoided. In addition, maintaining the range of voltages at the receiver 208 as narrow as possible can reduce cost, improve efficiency, and allow a range of receivers to charge on the same transmitter 204.

A solution may be to limit the voltage at the receiver 208. For example, limits may be designed in (e.g., hardcoded limits in the transmitter 204) so that the highest transmit current will not cause destructive voltages on the receiver 208. Designs may use a regular but slow voltage feedback via a feedback channel 219 (e.g., a Bluetooth channel). Another solution may be to use an over-voltage protection (OVP) alert, in which a Bluetooth signal is sent to shut down the transmitter 204 before damage can result from the over-voltage condition.

However, such solutions may not be adequate for certain transient conditions, where rapid high voltage excursions caused by transmitter currents that are below maximum values may nonetheless be detrimental to the electronics in the receiver 208. For example, the use of feedback via a communication channel 219 may be too slow to respond to such transients. An OVP alert mechanism can cause a system shutdown, which may protect the system from such transients, but is likely to result in a poor user experience (shutdown but no charge).

The discussion will now turn to a description of receive circuitry (e.g., 210, FIG. 2) in a PRU in accordance with the present disclosure. Referring to FIG. 4, receive circuitry 400 in a PRU (not shown), in some embodiments, may include a resonator circuit 422. The resonator circuit 422 may couple to an externally generated time varying magnetic field 42 to produce a time varying signal 44. In some embodiments, the resonator circuit 422 may include a receive coil 402 electrically connected to a reactive network 404. In some embodiments, for example, the receive coil 402 may be a coil of wire. In other embodiments, the receive coil 402 may be trace formed on a printed circuit board (PCB) in the shape of a coil, and so on.

In some embodiments, the receive coil 402 may have a fixed resonant frequency, Fᵣₑₛₒₙₐₙₜ. Accordingly, the reactive network 404 and receive coil 402 may define a resonant circuit having a frequency Fᵣₑₛₒₙₐₙₜ in order to achieve a given level of coupling with the magnetic field 42. The reactive network 404 may comprise any suitable network of one or more resistive devices and/or reactive devices, such as inductors, capacitors, etc. FIG. 3 illustrates an example of reactive components, namely capacitors 354, 356, that may constitute reactive network 404.

The receive circuitry 400 may include a rectifier circuit 406 electrically connected to the resonator circuit 422. The rectifier circuit 406 may include an output 408. The rectifier circuit 406 may be configured to produce a DC signal at its output 408 in response to the time varying signal 44 from the resonator circuit 422.

The receive circuitry 400 may include a variable impedance circuit 424 electrically connected as an electrical load to the output 408 of the rectifier circuit 406. In accordance with the present disclosure, an impedance of the variable impedance circuit 424 may vary and thus change the loading on rectifier circuit 406. This aspect of the present disclosure will be discussed in more detail.

In some embodiments, the variable impedance circuit 424 may comprise a variable load 412 and a controller (control circuit) 414. In some embodiments, the variable load 412 may act as a resistive load. In other embodiments, the variable load 412 may act as a reactive load. In still other embodiments, variable load 412 may act as a combination of resistive load and reactive load.

In some embodiments, the controller 414 may be configured to sense a voltage level Vₒᵤₜ at the output 408 of the rectifier circuit 406 and produce a control signal 414a based on the sensed voltage level. In other embodiments, the controller 414 may be configured to sense a current flow Iₒᵤₜ at the output 408; the control signal 414a may be based on current flow. In still other embodiments, the controller 414 may generate a control signal 414a based on Vₒᵤₜ and Iₒᵤₜ. The control signal 414a may be provided to the variable load 412 to control the impedance presented by the variable load 412. Although not illustrated, in other embodiments, the voltage level Vₒᵤₜ and current flow Iₒᵤₜ may be sensed using separate sense circuits. See FIG. 7, for example.

Operation of the receive circuitry 400 shown in FIG. 4 will now be explained in connection with the process depicted in FIG. 5. Referring to FIGS. 4 and 5, at block 502, the receive coil 402 may couple to the externally generated magnetic field 42. If the magnetic field 42 is a time varying (e.g., AC) field, this can result in a time varying signal 44 at the output of the resonator circuit 422.

At block 504, the rectifier circuit 406 may produce a DC signal at its output 408 in response to the time varying signal 44. The DC signal, for example, may provide DC power to device electronics (not shown) in a PRU that incorporates the receive circuitry 400. Merely as examples, the DC power may be used recharge a battery, drive a display, and so on.

At block 506, the controller 414 may sense an electrical characteristic of the DC signal. In some embodiments, for example, the controller 414 may be configured to sense a voltage level of the DC signal. In other embodiments, the controller 414 may be configured to sense a current flow of the DC signal. In other embodiments, the controller 414 may be configured to sense both the voltage level of the DC signal and the current flow of the DC signal.

At block 508, the controller 414 may generate a control (ctl) signal based on the sensed electrical characteristic(s) of the DC signal. In some embodiments, for example, the controller 414 may compare (e.g., using a suitable comparator circuit, not shown) a sensed voltage level with a predetermined threshold value. In response to the sensed voltage exceeding the predetermined threshold value, the controller 414 may assert or otherwise generate a control signal 414a, for example, to indicate an overvoltage condition.

In some embodiments, the predetermined threshold value in the controller 414 may be set equal to an overvoltage value that represents the overvoltage condition. Accordingly, the variable impedance circuit 424 may operate as a “limiting load” to limit the voltage level at the output 408 to a safe operating voltage of the PRU. In other embodiments, the predetermined threshold value may be set to a value lower than the overvoltage value. Using a value lower than the overvoltage limit may allow for preemptive action in order to reduce the output voltage before an overvoltage condition occurs.

In other embodiments, the controller 414 may use a sensed current flow of the DC signal as a criterion to control the variable load 412, e.g., in order to maintain a certain current flow at the output 408. The controller 414 may use a sensed voltage level and a sensed current flow (e.g., sensing a power level) of the DC signal as a criterion to control the variable load 412, e.g., in order to maintain a certain level of power delivered to the device electronics of the PRU. The controller 414 may use still other criteria for controlling the variable load 412, or combinations of these and other criteria for controlling the variable load 412.

At block 510, the variable load 412 may be configured to respond to the asserted control signal 414a that results in a change in its impedance. In some embodiments, for example, the impedance of the variable load 412 may decrease. Since there is an equivalent source resistance R_{equiv} at the output 408 of the rectifier circuit 406, the source resistance and the impedance of the variable load 412 define a voltage divider, and so decreasing the impedance of the variable load 412 can reduce the output voltage Vₒᵤₜ.

In some embodiments, instead of using a threshold as the trigger for generating the control signal 414a, voltage limiting action of the variable impedance circuit 424 can be continuous. There need not be a discrete change in load resistance of the variable load 412 due to crossing a threshold, but rather a continuously changing load resistance of the variable load 412. In some embodiments, the variable load 412 may be varied as a function Vₒᵤₜ. In other embodiments, the variable load 412 may be varied as a function Iₒᵤₜ. In other embodiments, the variable load 412 may be varied as a function of power (e.g., Vₒᵤₜ×Iₒᵤₜ).

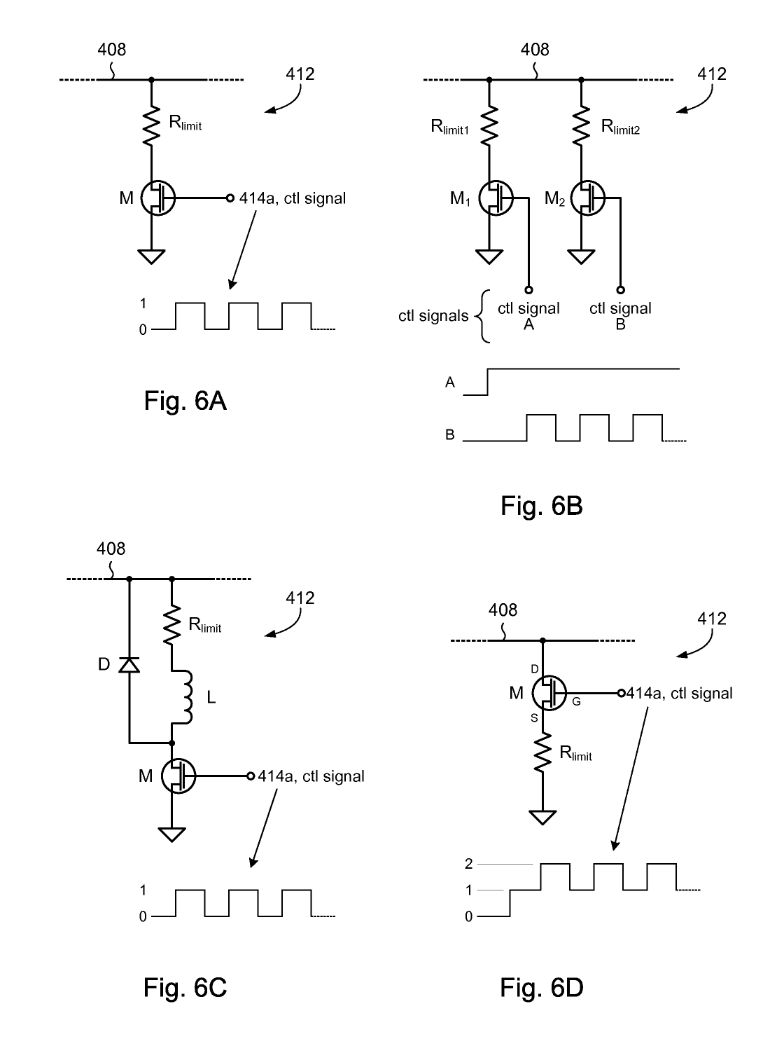

FIGS. 6A-6D show illustrative embodiments of the variable load 412 in accordance with the present disclosure. Referring to FIG. 6A, for example, in some embodiments, the variable load 412 may comprise a fixed-value limiting resistor Rₗᵢₘᵢₜ electrically connected in series with a switching device M. The switching device M may be a field effect transistor (FET), a bipolar transistor, a unijunction transistor (UJT), or any other suitable switching device. The switching device M can switch the limiting resistor Rₗᵢₘᵢₜ into and out of the output 408 of rectifier circuit 406.

In some embodiments, the control signal 414a may be a pulse width modulated (PWM) waveform. The controller 414 (FIG. 4) may vary the duty cycle of the PWM signal to vary the amount of load resistance at the output 408 of the rectifier circuit 406; e.g., a higher duty cycle can result in more ON time in switching device M and thus a higher resistance and vice-versa a lower duty cycle can result in a lower resistance. In some embodiments, where power level is the criterion, the controller 414 may determine power P based on: P=NVₒᵤₜ²/Rₗᵢₘᵢₜ, where N is duty cycle.

Referring to FIG. 6B, in some embodiments, the variable load 412 may comprise two or more limiting resistors Rₗᵢₘᵢₜ₁, Rₗᵢₘᵢₜ₂ switched by respective switches M₁, M₂. Such configurations allow for adjustment of both power and modulation depth. In addition, the multiple switched resistor legs allow the power to be spread over a greater number of components. In some embodiments, the controller 414 (FIG. 4) may drive one or more of these switches with a control signal (B), and/or one of more of these switches with a steady control signal (A). Merely as an example, suppose Rₗᵢₘᵢₜ₁ and Rₗᵢₘᵢₜ₂ are 10Ω resistors. If Rₗᵢₘᵢₜ₁ is turned ON (e.g., by control signal A) and Rₗᵢₘᵢₜ₂ is switched by control signal B, the variable load 412 can provide a resistive load between 5Ω and 10Ω depending on the duty cycle of control signal B.

Referring to FIG. 6C, in some embodiments, the variable load 412 may comprise a limiting resistor Rₗᵢₘᵢₜ electrically connected in series with an inductor L, and a diode D electrically connected in parallel with the resistor/inductor leg. A switching device M may be electrically connected in series with the resistor/inductor leg and the diode D. Such a configuration may reduce current transients, which can tend to reduce electromagnetic interference (EMI) by reducing edge rate and increasing available power handling by spreading heating effects from the power regulation across several components.

Referring to FIG. 6D, in some embodiments, the variable load 412 may comprise a current source configuration comprising switching device M electrically connected in series with a limiting resistor Rₗᵢₘᵢₜ. For example, the switching device M may be an N-channel FET with resistor Rₗᵢₘᵢₜ electrically connected at the source to create a constant current load, where current is proportional to the voltage on the gate. Accordingly, the control signal 414a may have an analog component in addition in its PWM signal. For example, where the voltage level labeled ‘1’ may be a nominal current draw and the voltage labeled ‘2’ may be a step up. The levels can be selected so the average power provides the desired overall power.

In accordance with the present disclosure, the controller 414 (FIG. 4) may further modulate the control signal 414a to include a message that can be communicated to a power transmitting unit (PTU, not shown) concurrently while providing overvoltage protection. In some embodiments, the controller 414 may modulate the control signal 414a in such a way as to control the impedance of the variable load 412 in order to accomplish the function of providing overvoltage protection while at the same time communicating a message to the PTU. For example, in addition to varying the duty cycle of control signal 414a to control impedance, an additional modulation may be superimposed on the control signal 414a to convey a message or other data to the PTU. This aspect of the present disclosure will be described in more detail below.

The discussion will now turn to a description of transmit circuitry (e.g., 206, FIG. 2) in a PTU (not shown) in accordance with the present disclosure. Referring to FIG. 7, transmit circuitry 700 in some embodiments may include an oscillator 702 to generate a time varying signal. The oscillator 702 may connect to a driver (power amp) 704, which may be configured to produce a drive signal to drive a transmit coil 708. A reactive network 706 may be electrically connected to the transmit coil 708. In some embodiments, the transmit coil 708 may be a coil of wire. In other embodiments, the transmit coil 708 may be trace formed on a printed circuit board (PCB) in the shape of a coil, and so on. The drive signal generated by power amp 704 can drive transmit coil 708 to generate an external time varying magnetic field 72. An external circuit 74 (e.g., of a PRU) may couple to the magnetic field 72.

In some embodiments, the transmit coil 708 may have a fixed resonant frequency, Fᵣₑₛₒₙₐₙₜ. Accordingly, the reactive network 706 and transmit coil 708 may define a resonant circuit in order to generate a magnetic field 72 at the frequency Fᵣₑₛₒₙₐₙₜ, allowing for a receiver (e.g., 400, FIG. 4) operating at the same resonant frequency to efficiently couple to the magnetic field 72. The reactive network 706 may comprise any suitable network of one or more resistive devices and/or reactive devices, such as inductors, capacitors, etc. FIG. 3 illustrates an example of reactive components, namely capacitors 354, 356, that may constitute reactive network 706.

The transmit circuitry 700 may include a controller 712. In some embodiments, the transmit circuitry 700 may include a sense circuit 722 configured to sense a voltage V_{senseTX} across the transmit coil 708. In other embodiments, the transmit circuitry 700 may include a sense circuit 724 configured to sense a current flow I_{senseTX} into the transmit coil 708. In other embodiments, the transmit circuitry 700 may be configured to sense both the voltage V_{senseTX} across the transmit coil 708 and the current flow I_{senseTX} into the transmit coil 708. Referring for a moment to FIG. 7A, in some embodiments, the transmit circuitry 700 may include a sense circuit 726 configured to sense the current flow I_{sensePA} into the power amp 704. The controller 712 may be configured to assert a control signal 414a to control the power amp 704 based on one or more of the sensed parameters V_{senseTX}, I_{senseTX}, and I_{sensePA}.

If the receive coil of the external circuit 74 draws more or less power from the magnetic field 72, the change in power drawn can manifest itself as a change in the impedance of transmit coil 708. Consider receive circuitry 400 in FIG. 4, for example. As explained above, in response to sensing a predetermined voltage condition at output 408, the variable impedance circuit 424 may alter its impedance. This can affect the amount of power that receive coil 402 draws from the externally generated magnetic field 42. A change in power drawn by the receive coil 402 may manifest itself in the transmit circuitry 700 as a corresponding change in the impedance of transmit coil 708. Changes in the impedance of transmit coil 708, in turn, may be detected by sensing any one of the foregoing parameters V_{senseTX}, I_{senseTX}, and I_{sensePA}, or combinations of one or more of V_{senseTX}, I_{senseTX}, and I_{sensePA}. The controller 712 may be configured to respond to changes in a sensed parameter(s) by altering the amount of power output of the power amp 704.

As noted above, the controller 414 in receive circuitry 400 may further modulate the control signal 414a to not only provide overvoltage protection by controlling the impedance of variable load 412, but at the same time incorporate a message, or more generally any kind of data, that can be conveyed to and detected by the PTU. As explained above, the duty cycle of the control signal 414a may be modulated to control the impedance of variable load 412 to provide overvoltage protection. At the same time, the control signal 414a may be further modulated (or the modulation for the overvoltage protection may be done in such a way or have a particular characteristic/signature) to incorporate a message or other data that can be detected by the PTU. This aspect of the present disclosure will be described in more detail below.

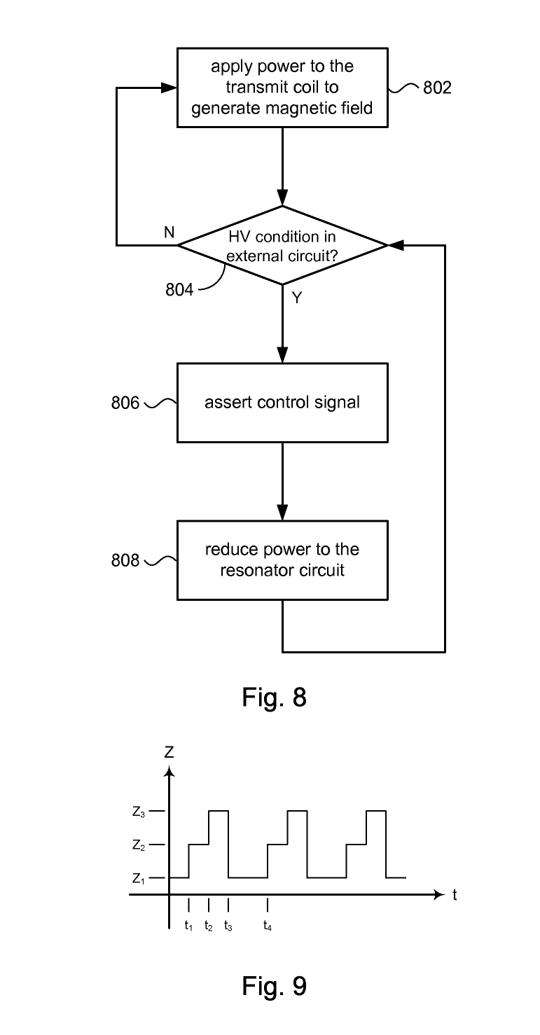

Operation of transmit circuitry 700 will now be explained in connection with the process depicted in FIG. 8. For purposes of explanation, receive circuitry 400 (FIG. 4) will serve as an example of external circuit 74. At block 802, the controller 712 may control the power amp 704 to drive the transmit coil 708; e.g., as an initial operating condition the transmit coil 708 might be driven at full power. The resulting magnetic field that may be generated may couple to the external circuit 74, namely receive circuitry 400.

At block 804, the controller 712 may detect a high voltage (HV) condition in the external circuit 74 (e.g., of a PRU). For example, if a predetermined voltage condition exists at output 408 of receive circuitry 400 (e.g., the voltage at output 408 exceeds a predetermined threshold), the variable impedance circuit 424 may vary its impedance and thus alter the power drawn from the magnetic field 72 by receive coil 402. A resulting corresponding change in the impedance of transmit coil 708 may appear as changes in V_{senseTX}, I_{senseTX}, and I_{sensePA}. An HV condition in a PRU may be signaled when a sensed parameter (V_{senseTX}, I_{senseTX}, I_{sensePA}) crosses a predetermined threshold value. In some embodiments, an HV condition may be signaled based on parameters (e.g., power, impedance, etc.) calculated from the sensed parameters.

At block 806, the controller 712 may assert a control signal to control the power output of the power amp 704 in response to an HV condition. In some embodiments, the transmit circuitry 700 may be embodied in a PTU configured for coupling to multiple PRUs. Accordingly, at block 808, in accordance with the present disclosure, the controller 712 may reduce the power (e.g., transmit current) to the transmit coil 708 when an HV condition occurs in a PRU, rather than cutting off power completely, so as to minimize disruption to other PRUs in the wireless charging system. In some embodiments, the controller 712 may reduce the power to the transmit coil 708 at a fixed rate (e.g., some number of units of current per unit of time) until the HV condition is no longer present. In other embodiments, the controller 712 may modulate or otherwise control current into the transmit coil 708 in a continuously variable fashion using an appropriate control algorithm.

When power to the transmit coil 708 is reduced, that in turn can reduce the amount of power that is received at the receive circuitry 400. Accordingly, the sensed voltage at output 408 in the receive circuitry 400 may drop, which in turn may cause the controller 414 to disable or otherwise adjust the amount of resistance presented by the load circuit 412. This can restore the original impedance of the transmit coil 708, which in turn may restore the original values of V_{senseTX}, I_{senseTX}, and I_{sensePA}, thus signaling the end of the HV condition.

As explained above, in accordance with the present disclosure, the variable impedance circuit 424 (FIG. 4) may vary its impedance (e.g., resistance) in a predetermined manner. In some embodiments, for example, in response to the sensed voltage level of output 408 exceeding a predetermined value, the variable impedance circuit 424 may set its impedance to a given value in accordance with the sensed voltage level.

In other embodiments, the variable impedance circuit 424 may modulate its impedance in a time varying manner. Referring to FIG. 9, for example, the controller 414 may modulate its control signal 414a so that the impedance of load circuit 412 varies in steps. The impedance may increase from Z₁-Z₂ between times t₁ and t₂, from Z₂-Z₃ between t₂ and t₃, and drop back to Z₁ after time t₃. The pattern may repeat beginning at time t₄. This modulation may be detected in the transmit circuitry as corresponding modulations in V_{senseTX}, I_{senseTX}, and I_{sensePA}. Accordingly, an HV condition in a PRU may be signaled when the controller 712 detects such modulations in a sensed parameter (V_{senseTX}, I_{senseTX}, I_{sensePA}). In some embodiments, the HV condition in a PRU may be deemed to have cleared when the modulation is no longer detected. In other embodiments, termination of an HV condition may be signaled using a different modulation. Persons of ordinary skill will appreciate, of course, that the modulation shown in FIG. 9 is merely illustrative and that any suitable modulation may be used in other embodiments.

More generally, the modulation may serve as a low bit rate signaling method to communicate data from the PRU to the PTU at the same time that overvoltage protection is happening. Accordingly, the variable impedance circuit 424 can be modulated (e.g., using control signal 414a) in a way that simultaneously provides overvoltage protection and conveys a message or other data to the PTU. Thus, modulations in the variable impedance circuit 424 detected by the PTU may (1) inform the PTU to adjust its transmit power in order to avoid overvoltage and/or (2) provide information to the PTU that does not necessarily relate to overvoltage protection. This may allow for a configuration that may accomplish both the signaling and protection in overvoltage conditions while not having to immediately rely on other communication mechanisms that may introduce delays in the ability to protect circuitry in more extreme overvoltage conditions.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

The following is claimed:

1. An apparatus for wireless power transfer comprising:
a resonator circuit configured to couple to an externally generated magnetic field and to generate a time varying signal in response to the externally generated magnetic field;
a rectifier circuit electrically connected to the resonator circuit, the rectifier circuit having an output and configured to produce from the time varying signal of the resonator circuit a DC signal at the output of the rectifier circuit;
a variable impedance circuit electrically connected as an electrical load to the output of the rectifier circuit; and
a control circuit electrically connected to the rectifier circuit and configured to produce a control signal based on an electrical characteristic of the DC signal produced at the output of the rectifier circuit,
the variable impedance circuit electrically connected to the control circuit and configured to change an impedance of the variable impedance circuit in response to the control signal of the control circuit.

2. The apparatus of claim 1, wherein the variable impedance circuit comprises a resistive load electrically connected to the output of the rectifier circuit.

3. The apparatus of claim 1, wherein the control signal is configured to modulate the impedance of the variable impedance circuit in a predetermined manner.

4. The apparatus of claim 3, wherein the control signal is configured to modulate the impedance of the variable impedance circuit depending on a magnitude of the electrical characteristic of the DC signal produced at the output of the rectifier circuit.

5. The apparatus of claim 1, wherein the electrical characteristic of the DC signal produced at the output of the rectifier circuit comprises one or more of a voltage level of the DC signal or an electrical current flow of the DC signal.

6. The apparatus of claim 1, wherein the variable impedance circuit comprises a first resistor electrically connected in series with a first switching device, wherein the control signal controls conduction in the first switching device to vary a combined impedance of the first resistor and the first switching device.

7. The apparatus of claim 6, wherein the first resistor and the first switching device define a first leg, wherein the variable impedance circuit further comprises a second leg in parallel with the first leg, the second leg comprising a second resistor electrically connected in series with a second switching device, wherein the control signal controls conduction in the second switching device to vary a combined impedance of the second resistor and the second switching device.

8. The apparatus of claim 1, wherein the variable impedance circuit comprises a resistor electrically connected in series with a reactive device, a diode electrically connected in parallel with the reactive device/resistor combination, and a switching device electrically connected in series with both the diode and the reactive device/resistor combination, wherein the control signal controls conduction in the switching device.

9. The apparatus of claim 1, wherein the electrical characteristic corresponds to a voltage or electrical current level being above a threshold corresponding to an over-voltage condition.

10. The apparatus of claim 9, wherein the variable impedance circuit is configured to change the impedance of the variable impedance circuit to reduce the voltage or electrical current level, the impedance of the variable impedance circuit changing according to a predetermined manner based on the control signal to form a message detectable by a transmitter generating the externally generated magnetic field, the message indicative of the over-voltage condition.

11. A method for wireless power transfer comprising:
coupling to an externally generated magnetic field to produce a time varying signal;
producing from the time varying signal a DC signal at an output of a circuit;
sensing an electrical characteristic of the DC signal produced at the output of the circuit;
generating a control signal in response to the electrical characteristic sensed; and
varying an impedance of a load electrically connected to the output of the circuit in response to the control signal generated.

12. The method of claim 11, wherein varying the impedance of the load includes modulating the impedance of the load in a predetermined manner.

13. The method of claim 12, wherein varying the impedance of the load includes modulating the impedance of the load in a manner that depends on a magnitude of the electrical characteristic of the DC signal.

14. The method of claim 11, wherein the electrical characteristic of the DC signal includes one or more of a voltage level of the DC signal or a current flow of the DC signal.

15. The method of claim 11, wherein varying the impedance of a load includes operating a switching device of the load with the control signal.

16. The method of claim 11, wherein the control signal is a pulse width modulated signal.

17. An apparatus for wireless power transfer comprising:
a resonator circuit configured to generate a magnetic field that can couple to an external circuit for wireless transmission of power to the external circuit;
a power circuit electrically connected to the resonator circuit and configured to provide power to the resonator circuit to generate the magnetic field;
a sense circuit electrically connected to one or more of the resonator circuit or the power circuit and configured to sense one or more of a voltage level in the resonator circuit, a current flow in the resonator circuit, or a current flow in the power circuit; and
a controller electrically connected to the power circuit and configured to control the power circuit to vary the power provided to the resonator circuit in response to an indication that a predetermined voltage condition exists at an output of the external circuit, the indication being based on a parameter sensed by the sense circuit including one or more of a sensed voltage level in the resonator circuit, a sensed current flow in the resonator circuit, or a sensed current flow in the power circuit.

18. The apparatus of claim 17, wherein the predetermined voltage condition is a voltage level at the output of the external circuit being equal to or greater than a predetermined threshold value.

19. The apparatus of claim 18, wherein the predetermined threshold value is less than an overvoltage voltage level in the external circuit.

20. The apparatus of claim 17, wherein the indication is based on one or more of the sensed voltage level in the resonator circuit, the sensed current flow in the resonator circuit, and the sensed current flow in the power circuit being modulated in a predetermined manner.
